(19) United States
(12) Patent Application Publication
(10) Pub. No.: US 2018/0366562 A1
(43) Pub. Date: Dec. 20, 2018

(54) METHODS OF FORMING INTEGRATED CIRCUIT STRUCTURES INCLUDING NOTCH WITHIN FIN FILLED WITH RARE EARTH OXIDE AND RELATED STRUCTURE

(71) Applicant: GLOBALFOUNDRIES INC., Grand Cayman (KY)

(72) Inventors: Xusheng Wu, Ballston Lake, NY (US); Chengwen Pei, Danbury, CT (US); Ziyan Xu, San Diego, CA (US)

(21) Appl. No.: 15/627,715

(22) Filed: Jun. 20, 2017

(51) Int. Cl. H01L 29/66; H01L 29/78; H01L 29/06

(52) U.S. Cl. CPC H01L 29/66795; H01L 29/0653; H01L 29/785

(57) ABSTRACT

The disclosure is directed to methods of forming an integrated circuit structure and a related structure. One method may include: forming a gate structure over a fin, the fin being formed over a substrate and the gate structure defining a channel region beneath the gate structure within the fin; forming a notch within the fin and beneath the channel region by laterally etching the fin on opposing sides of the channel region; forming a rare-earth oxide (REO) within the notch and extending along a top surface of the fin outside of the notch; and forming a source region and a drain region on opposing sides of the channel region and over the REO that is disposed along the top surface of the fin.

### BACKGROUND

### Technical Field

The present disclosure relates to integrated circuit structures, and more particularly, to methods of forming an integrated circuit structure including a notch within a fin that is filled with a rare earth oxide and a related integrated circuit structure.

### Related Art

In integrated circuit (IC) structures, a transistor is a critical component for implementing digital circuitry designs. Generally, a transistor includes three electrical terminals: a source, a drain, and a gate. By applying different voltages to the gate terminal, electric current from the source to the drain can be turned on and off. A common type of transistor is a metal oxide field effect transistor (MOSFET). One type of MOSFET structure is a “FINFET.” which may be formed upon a semiconductor-on-insulator (SOI) layer and buried insulator layer. A FINFET can include a semiconductor structure etched into a “fin” shaped body, with one side of the fin acting as a source terminal and the other side of the fin acting as a drain terminal. A gate structure, typically composed of polysilicon and/or a metal, can be formed around one or more of the semiconductor fins. By applying a voltage to the gate structure, an electrically conductive channel can be created between the source and drain terminals of each fin in contact with the gate.

In some cases, a FINFET may be desirable in IC structures which do not include an SOI layer with a corresponding buried insulator layer. For example, processors for mobile applications can include forming transistor structures on a bulk substrate instead of an SOI-type structure. Planar devices can be formed conventionally within the bulk substrate without substantial modifications. A FINFET may also be adapted for use on a bulk substrate material instead of SOI. However, FINFETs on bulk substrates can have a leakage path in the sub-fin region, i.e., the region of the fin below the gate. This leads to significant drain to source current, i.e., punch-through current, which has to be suppressed with a punch-through stop implant. A punch-though stop implant includes implanting dopants to prevent expansion of the drain depletion into the source terminal. However, such implanting leads to unwanted high doping concentrations in the fin which degrades carrier mobility and introduces within-fin non-uniformities.

### SUMMARY

A first aspect of the disclosure is directed to a method for forming an integrated circuit structure. The method may include: forming a gate structure over a fin, the fin being formed over a substrate and the gate structure defining a channel region beneath the gate structure within the fin; forming a notch within the fin and beneath the channel region by laterally etching the fin on opposing sides of the channel region; forming a rare-earth oxide (REO) within the notch and extending along a top surface of the fin outside of the notch; and forming a source region and a drain region on opposing sides of the channel region and over the REO that is disposed along the top surface of the fin.

A second aspect of the disclosure is directed to a method of forming an integrated circuit structure. The method may include: forming a fin from a substrate such that the fin is disposed over a remaining portion of the substrate; forming a gate structure perpendicular to and substantially surrounding the fin such that a channel region is defined beneath the gate structure within the fin; removing a portion of the fin that is adjacent to the channel region from opposing sides of the channel region such that the channel region remains disposed beneath the gate structure; forming a notch within the fin and beneath the channel region by laterally etching the fin on opposing sides of the channel region; forming a rare-earth oxide (REO) to substantially fill the notch and extending along a top surface of the fin outside of the notch; and forming a source region and a drain region on opposing sides of the channel region and over the REO that is disposed along the top surface of the fin.

A third aspect of the disclosure is directed to an integrated circuit structure. The integrated circuit structure may include: a fin over a substrate; a gate structure perpendicular to and substantially surrounding the fin, the gate structure defining a channel region thereunder within the fin; a source region and a drain region over the fin on opposing sides of the channel region; and a rare-earth oxide (REO) disposed between the source region and fin, and between the drain region and the fin, the REO being partially disposed beneath the channel region within the fin.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIGS. 1-6 show cross-sectional views of an integrated circuit structure undergoing aspects of a method according to embodiments of the disclosure, wherein FIG. 6 shows a resulting integrated circuit structure.

FIG. 7 shows a cross-sectional view of another resulting integrated circuit structure according to embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The present disclosure relates to integrated circuit structures, and more particularly, to methods of forming an integrated circuit structure including a notch within a fin that is filled with a rare earth oxide and a related integrated circuit structure. Aspects of the disclosure described herein reduce punch through current and provide a means for isolating the source region and drain region from the substrate.

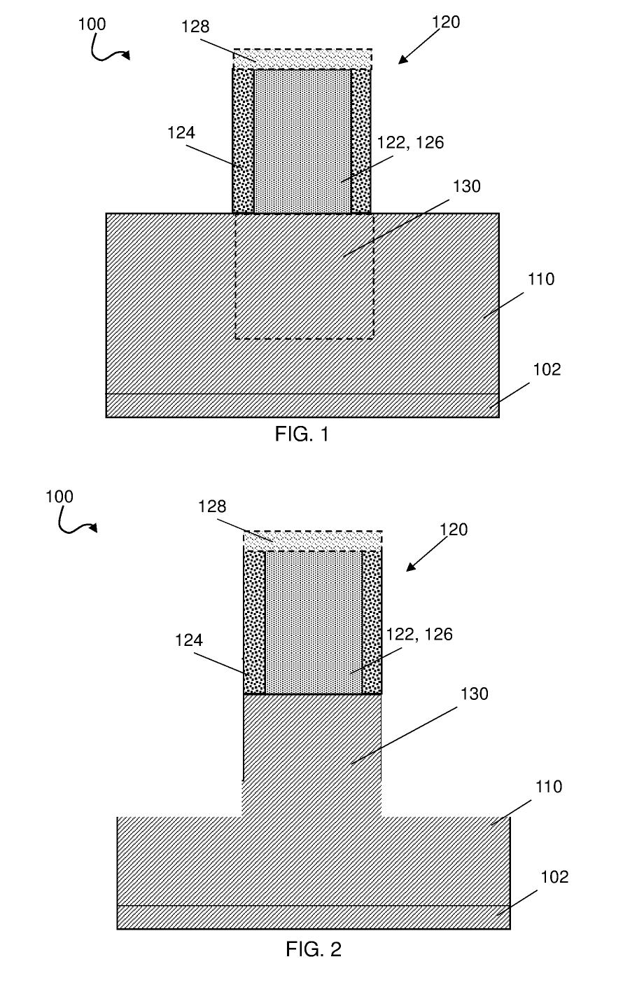

Referring now to FIG. 1, a cross-sectional view of a preliminary integrated circuit (IC) structure 100 is shown. IC structure 100 may include a substrate 102 having one or more fins (one shown) 110 formed therefrom. Substrate 102 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entirety of substrate 102 may be strained. While substrate 102 is shown as including a single layer of semiconductor material, it is emphasized that the teachings of the disclosure are equally applicable to semiconductor-on-insulator (SOI) substrates. As known in the art, SOI substrates may include a semiconductor layer on an insulator layer on another semiconductor layer (not shown). The semiconductor layers of an SOI substrate may include any of the semiconductor substrate materials discussed herein. The insulator layer of the SOI substrate may include any now known or later developed SOI substrate insulator such as but not limited to silicon oxide.

Fins 110 may be formed from substrate 102, e.g., by patterning a mask and etching, such that fin overlies a remaining portion of substrate 102. Where substrate 102 includes an SOI substrate, fins 110 may be formed from the upper semiconductor layer over the insulator layer. As used herein “etching” generally refers to the removal of material from a substrate or structures formed on the substrate by wet or dry chemical means. In some instances, it may be desirable to selectively remove material from certain areas of the substrate. In such an instance, a mask may be used to prevent the removal of material from certain areas of the substrate. There are generally two categories of etching, (i) wet etch and (ii) dry etch. Wet etching may be used to selectively dissolve a given material and leave another material relatively intact. Wet etching is typically performed with a solvent, such as an acid. Dry etching may be performed using a plasma which may produce energetic free radicals, or species neutrally charged, that react or impinge at the surface of the wafer. Neutral particles may attack the wafer from all angles, and thus, this process is isotropic. Ion milling, or sputter etching, bombards the wafer with energetic ions of noble gases from a single direction, and thus, this process is highly anisotropic. A reactive-ion etch (RIE) operates under conditions intermediate between sputter etching and plasma etching and may be used to produce deep, narrow features, such as trenches. While one fin 110 is shown, it is to be understood that any number of fins may be employed without departing from aspects of the disclosure.

IC structure 100 may also include an isolation region (not shown) over substrate 102 to separate device regions (not individually referenced). FIG. 1 shows a cross-sectional view of IC structure 100 taken along fin 110. Therefore, in this embodiment, isolation region may be disposed on opposing sides of fin 110 (in front of and behind fin 110 on the page) over substrate 102 such that the isolation region separates adjacent fins. The isolation region may include a shallow trench isolation (STI) which may be formed by etching a trench within substrate 102 and filling, e.g., by deposition, the trench with an insulator, e.g., silicon oxide, silicon nitride, silicon oxynitride. As used herein, the term “depositing” may include any now known or later developed technique appropriate for deposition, including but not limited to, for example: chemical vapor deposition (CVD), low-pressure CVD (LPCVD), plasma-enhanced CVD (PECVD), semi-atmosphere CVD (SACVD) high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation.

Still referring to FIG. 1, one or more gate structures 120 (one shown) may be formed over fin 110. Gate structure 120 may be formed such that it is perpendicular to and substantially surrounds a portion of fins 110. It is to be understood that in the embodiment shown, fin 110 runs left to right across the page and gate structure 120 runs into and out of the page such that gate structure 120 overlaps fin 110. In one embodiment, gate structure 120 may include a dummy gate structure. A dummy gate structure refers to a sacrificial gate structure that holds the position for a later formed active metal gate and is better able to withstand the more severe processing conditions so as to prevent damage to the active metal gate material that would occur if the active metal gate material were in place during certain processing. In another embodiment, gate structure 120 may include an active gate structure.

Where gate structure 120 includes a dummy gate structure, gate structure 120 may be formed within IC structure 100 such that dummy gate structure 120 is perpendicular to and overlaps fin 110. Dummy gate structure 120 may be formed by depositing and etching a dummy gate material, e.g., amorphous carbon, over IC structure 100 including fin 110 such that a dummy gate 122 remains. While not shown, the formation of dummy gate 122 may be preceded by the formation of a gate dielectric material as known in the art. After dummy gate 122 is formed, a spacer material (e.g., silicon oxide, silicon nitride) may be deposited over IC structure 100 including fin 110 and etched such that spacers 124 remain on opposing sides of dummy gate 122, thereby forming dummy gate structure 120.

Where gate structure 120 includes an active gate structure, gate structure 120 may be formed within IC structure 100 such that active gate structure 120 is perpendicular to and overlaps fin 110. Active gate structure 120 may be formed by depositing and etching active gate materials, e.g., a gate conductor 126, in a gate-first process. Subsequently, spacers 124 may be formed on opposing sides of gate structure 120 such that spacers 124 remain on opposing sides of active gate structure 120. However, in a gate-last process, active gate structure 120 may be formed after the forming of the source region and the drain region as will be described herein. In a gate-last process, a dummy gate, e.g., dummy gate 122, may be first formed over fin 110 as described above, and removed from between spacers 124 after the source region and the drain region are formed. Subsequently, active gate structure 120 may be formed between spacers 124 by forming the active gate materials therebetween. In such an embodiment, active gate structure 120 may be known as a replacement metal gate. Further, where gate structure 120 is an active gate structure, a gate cap layer 128 (e.g., silicon nitride, silicon oxide) may be formed (e.g., deposition, patterning a mask thereover and etching) over gate conductor 126 as shown in phantom.

In either embodiment, the active gate materials may include, for example, a gate conductor 126. Gate conductor 126 may include, for example, at least one of: titanium, titanium nitride, tungsten, tungsten nitride, copper, copper nitride, tantalum, tantalum nitride, alloys or combinations thereof. While not shown, it is to be understood that active gate structure 120 may also include other conventional active gate stack layers beneath gate conductor 126, for example, a layer having a high dielectric constant (high-k) layer, barrier layers, wetting layers, and work function metal layers. High-k layers may include a material having a dielectric constant greater than 4.0 such as, for example, at least one of: hafnium oxide, hafnium silicate, nitride hafnium silicate, zirconium oxide, zirconium silicate, titanium oxide, lanthanum oxide, yttrium oxide, aluminum oxide, or combinations thereof. Barrier and/or wetting layers may include, for example, titanium nitride. Work function metal layers may each act as a doping source, and a different work function setting metal can then be employed depending on whether a n-type field-effect-transistor (NFET) or a p-type field-effect-transistor (PFET) device is desired. Thus, the same gate conductor (gate conductor 126) can be used in each of the devices, yet a different (if so desired) work function setting metal can be used in one or more devices to obtain a different doping polarity. By way of example only, suitable work function setting metals for use in PFET devices include, but are not limited to: aluminum, dysprosium, gadolinium, and ytterbium. Suitable work function setting metals for use in NFET devices include, but are not limited to: lanthanum, titanium, and tantalum. In such embodiments, conductor 126 may be formed over the work function metal layers.

In either embodiment, i.e., whether gate structure 120 is a dummy gate structure or an active gate structure, a channel region 130 may be defined beneath gate structure 120 within fin 110. Turning now to FIG. 2, fin 110 may undergo vertical etching, e.g., RIE, such that a portion of fin 120 that is adjacent to channel region 130 is removed such that channel region 130 remains disposed beneath gate structure 120.

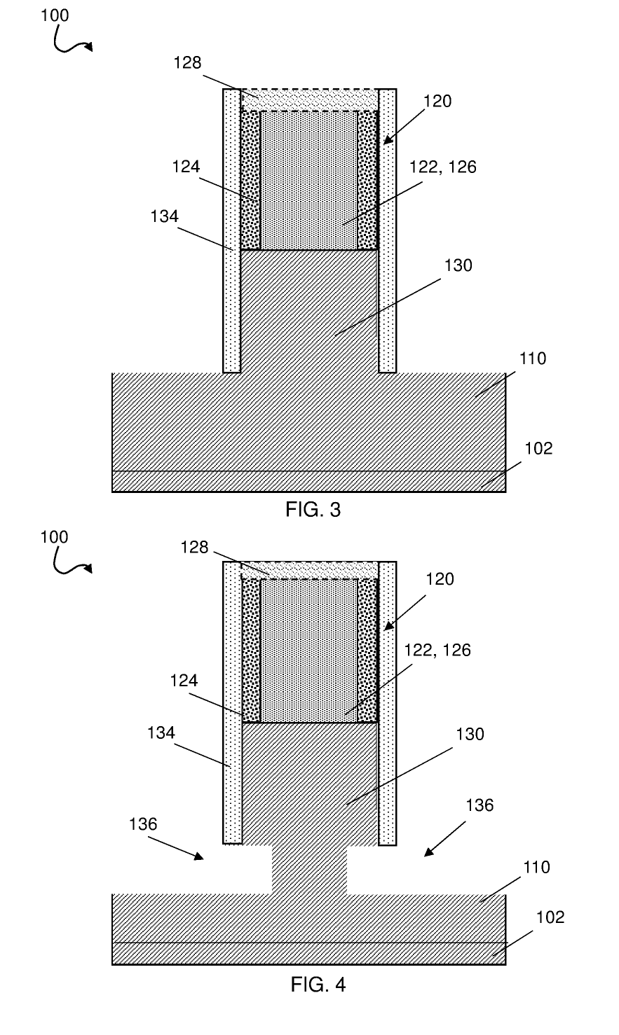

Turning now to FIGS. 3-4, one or more notches 136 (two shown) (FIG. 4) may be formed within fin 110 beneath channel region 130. Notches 136 may be formed by forming (e.g., depositing and etching) a sacrificial spacer 134 over fin 110, and adjacent to gate structure 120 and channel region 130 as shown in FIG. 3. Subsequently, sacrificial spacer 134 may be used as a mask during the forming of notches 136 as shown in FIG. 4. More specifically, portions of fin 110 may be removed (e.g., by etching) to form notches 136 beneath sacrificial spacers 134 and at least partially extending beneath channel region 130. In such an embodiment, forming of notches 136 may include vertically and laterally etching portions of fin 110 that are beneath sacrificial spacer 134 and channel region 130.

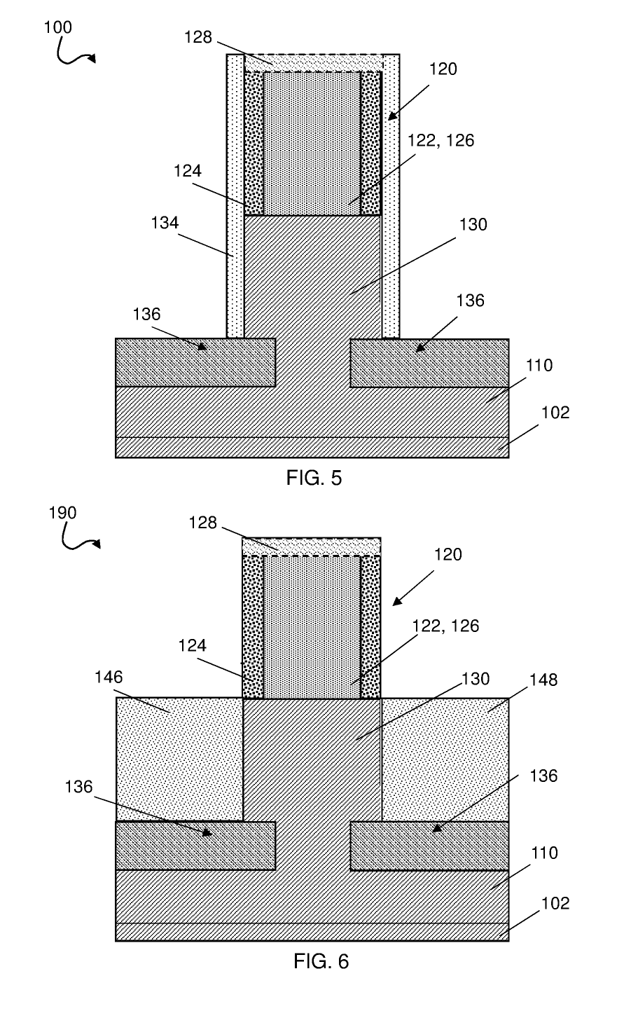

Turning now to FIG. 5, a rare earth oxide (REO) 142 may be formed, e.g., epitaxially grown or deposited, within notches 136 to substantially fill notches 136. Additionally, REO 142 is lattice matched to silicon and capable to grow on silicon and may extend outside of notches 136 and along a top surface of fin 110 such that REO 142 is disposed between fin 110 and source and drain regions formed thereover as will be described herein. The terms “epitaxial growth and/or deposition” and “epitaxially formed and/or grown” mean the growth of a semiconductor material or crystal oxide on a deposition surface of a semiconductor material, in which the semiconductor material being grown may have the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a (100) crystal surface may take on a (100) orientation. In some embodiments, epitaxial growth and/or deposition processes may be selective to forming on semiconductor surfaces, and may not form on dielectric surfaces, such as silicon dioxide or silicon nitride surfaces.

REO 142 may include, for example, at least one of or a compound of: cerium oxide, dysprosium oxide, erbium oxide, europium oxide, gadolinium oxide, holmium oxide, lanthanum oxide, lutetium oxide, neodymium oxide, praseodymium oxide, promethium oxide, samarium oxide, scandium oxide, terbium oxide, thulium oxide ytterbium oxide, or yttrium oxide. In some embodiments, REO 142 includes a material that has a lattice orientation that matches a lattice orientation of substrate 102, and therefore, fin 110. That is, REO 142 may be customized such that REO 142 includes a lattice that is matched to the lattice of substrate 102. For example, REO 142 may include a compound of two materials selected from the list of REO materials. In this example, the first material (A) may have a lattice that is larger than the lattice of substrate 102, and the second material (B) may have a lattice that is smaller than the lattice of substrate 102. In order to make a compound of materials AB, e.g., AxBy, the ratio of A to B, or the values of x and y in this example, may be optimized to obtain an REO compound having a lattice that is substantially similar to the lattice of substrate 102.

After REO 142 is formed, sacrificial spacer 134 may be removed and source region 146 and drain region 148 are each formed over REO 142 that is disposed over fin 110 on opposing sides of channel region 130 to provide a resulting IC structure 190 as shown in FIG. 6. Source region 146 and drain region 148 may be formed, for example, by epitaxial growth and/or deposition. Source region 126 and drain region 148 may include, for example, any conventional semiconductor source/drain material. In some embodiments, source region 146 and drain region 148 may be doped as known in the art, e.g., with n- or p-type dopants.

As shown in FIG. 6, resulting IC structure 190 may include fin 110 over substrate 102, gate structure 120 perpendicular to and substantially surrounding fin 110, channel region 130 being defined beneath gate structure 120, source region and drain region over fin 110 on opposing sides of channel region 130, and REO 142 disposed between source region 146 and fin 110 and also between drain region 148 and fin 110 on opposing sides of channel region 130. REO 142 may also be partially disposed beneath channel region 130 that is within fin 110. More specifically, REO 142 may be disposed within notches 136 on opposing sides of channel region 130 within fin 110. With a non-conductive oxide, e.g., REO 142 in place, source/drain punch through current is reduced and source region 146 and drain region 148 is isolated from the substrate 102.

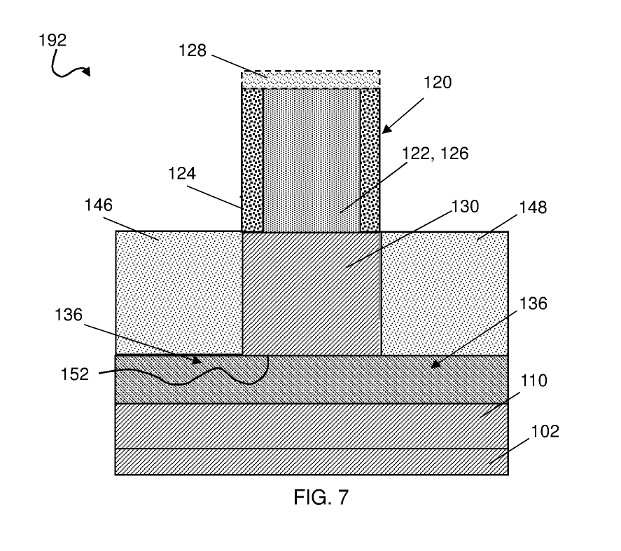

FIG. 7 shows a resulting IC structure 192 according to another embodiment of the disclosure. In this embodiment, the forming of notches 136 may include laterally etching fin 110 on opposing sides of channel region 130 until an opening 152 is created within fin 110 and beneath channel region 130. Opening 152 may extend from one side of channel region 130 to an opposing side of channel region 130 beneath channel region 130. Further, the forming of REO 142 may include forming REO 142 within opening 152 such that REO 142 extends from one side of channel region 130 to the opposing side of channel region 130 within opening 152. In this embodiment, the silicon, e.g., of fin 110, underneath channel region 130 is etched and refilled with REO 142 which is non-conductive material. As a result, channel region 130, source region 146, and drain region 148 are isolated from substrate 102 by REO 142 allowing gate structure 120 increased control of channel region.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s). “Substantially” refers to largely, for the most part, entirely specified or any slight deviation which provides the same technical benefits of the disclosure.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A method of forming an integrated circuit structure, the method comprising:
forming a gate structure over a fin, the fin being formed over a substrate and the gate structure defining a channel region beneath the gate structure within the fin;
forming a notch within the fin and beneath the channel region by laterally etching the fin on opposing sides of the channel region;
forming a rare-earth oxide (REO) within the notch and extending along a top surface of the fin outside of the notch; and
forming a source region and a drain region on opposing sides of the channel region and over the REO that is disposed along the top surface of the fin.

2. The method of claim 1, further comprising:
after the forming of the gate structure and prior to the forming of the notch, vertically etching the fin to remove a portion of the fin adjacent to the channel region such that the channel region remains disposed beneath the gate structure.

3. The method of claim 2, further comprising:
after the vertically etching of the fin and prior to the forming of the notch, forming a sacrificial spacer over the fin and adjacent to the gate structure,
wherein the forming of the notch includes laterally etching the fin on the opposing sides of the channel region and beneath the sacrificial spacer.

4. The method of claim 3, wherein the forming of the sacrificial spacer includes forming the sacrificial spacer on opposing sides of the gate structure such that the sacrificial spacer is adjacent to the channel region that is disposed beneath the gate structure.

5. The method of claim 3, further comprising:
after the growing of the REO in the notch and prior to the forming of the source region and drain region, removing the sacrificial spacer.

6. The method of claim 1, wherein the growing of the REO in the notch includes growing at least one of or a compound of: cerium oxide, dysprosium oxide, erbium oxide, europium oxide, gadolinium oxide, holmium oxide, lanthanum oxide, lutetium oxide, neodymium oxide, praseodymium oxide, promethium oxide, samarium oxide, scandium oxide, terbium oxide, thulium oxide ytterbium oxide, or yttrium oxide.

7. The method of claim 1, wherein the forming of the notch within the fin and beneath the channel region includes laterally etching the fin on opposing sides of the channel region until an opening is created within the fin and beneath the channel region, the opening extending from one side of the channel region to an opposing side of the channel region beneath the channel region.

8. The method of claim 7, wherein the growing of the REO in the notch includes growing the REO within the opening such that the REO extends from the one side of the channel region to the opposing side of the channel region within the opening.

9. The method of claim 1, wherein the growing of the REO includes growing a material that has a lattice orientation that matches a lattice orientation of the substrate.

10. A method of forming an integrated circuit structure, the method comprising:
forming a fin from a substrate such that the fin is disposed over a remaining portion of the substrate;
forming a gate structure perpendicular to and substantially surrounding the fin such that a channel region is defined beneath the gate structure within the fin;
removing a portion of the fin that is adjacent to the channel region from opposing sides of the channel region such that the channel region remains disposed beneath the gate structure;
forming a notch within the fin and beneath the channel region by laterally etching the fin on opposing sides of the channel region;
forming a rare-earth oxide (REO) to substantially fill the notch and extending along a top surface of the fin outside of the notch; and
forming a source region and a drain region on opposing sides of the channel region and over the REO that is disposed along the top surface of the fin.

11. The method of claim 10, further comprising:
after the removing of the portion of the fin that is adjacent to the channel region from opposing sides of the channel region and prior to the forming of the notch, forming a sacrificial spacer over the fin and adjacent to the gate structure such that the sacrificial spacer is disposed adjacent to and on opposing sides of the channel region,
wherein the forming of the notch includes laterally etching a portion of the fin on the opposing sides of the channel region and beneath the sacrificial spacer.

12. The method of claim 11, further comprising:
after the growing of the REO to fill the notch and prior to the forming of the source region and drain region, removing the sacrificial spacer.

13. The method of claim 10, wherein the growing of the REO includes growing at least one of: or a compound of cerium oxide, dysprosium oxide, erbium oxide, europium oxide, gadolinium oxide, holmium oxide, lanthanum oxide, lutetium oxide, neodymium oxide, praseodymium oxide, promethium oxide, samarium oxide, scandium oxide, terbium oxide, thulium oxide ytterbium oxide, or yttrium oxide.

14. The method of claim 10, wherein the forming of the notch within the fin and beneath the channel region includes laterally etching the fin on opposing sides of the channel region until an opening is created within the fin and beneath the channel region, the opening extending from one side of the channel region to an opposing side of the channel region beneath the channel region.

15. The method of claim 14, wherein the growing of the REO to fill the notch growing the REO within the opening such that the REO extends from the one side of the channel region to the opposing side of the channel region within the opening.

16. The method of claim 10, wherein the growing of the REO includes growing a material that has a lattice orientation that matches a lattice orientation of the substrate.

17. An integrated circuit structure comprising:
a fin over a substrate;
a gate structure perpendicular to and substantially surrounding the fin, the gate structure defining a channel region thereunder within the fin;
a source region and a drain region over the fin on opposing sides of the channel region; and
a rare-earth oxide (REO) disposed between the source region and fin, and between the drain region and the fin, the REO being partially disposed beneath the channel region within the fin.

18. The integrated circuit structure of claim 17, wherein the REO includes at least one or a compound of: cerium oxide, dysprosium oxide, erbium oxide, europium oxide, gadolinium oxide, holmium oxide, lanthanum oxide, lutetium oxide, neodymium oxide, praseodymium oxide, promethium oxide, samarium oxide, scandium oxide, terbium oxide, thulium oxide ytterbium oxide, or yttrium oxide.

19. The integrated circuit structure of claim 17, wherein the REO includes a material that has a lattice orientation that matches a lattice orientation of the substrate.

20. The integrated circuit structure of claim 17, wherein the REO is disposed beneath the channel region and extends from one side of the channel region to an opposing side of the channel region.
